(19) United States
(12) Patent Application Publication
(10) Pub. No.: US 2025/0287510 A1
(43) Pub. Date: Sep. 11, 2025

(54) FLEXIBLE MULTILAYER ELECTRONIC STRUCTURES

(71) Applicant: GRAPHENATON TECHNOLOGIES SA, Plan-les-Ouates (CH)

(72) Inventor: Patrick Muller, Chailly Montreux (CH)

(21) Appl. No.: 18/856,556

(22) PCT Filed: Apr. 11, 2023
(86) PCT No.: PCT/IB2023/053680

§ 371 Date: Oct. 11, 2024

(30) Foreign Application Priority Data
Apr. 12, 2022 (CH) CH000433/2022

(51) Int. Cl. H05K 3/12; H05K 1/02; H05K 3/46

(52) U.S. Cl. CPC H05K 3/125; H05K 1/0277; H05K 3/4644

(57) ABSTRACT

A method for manufacturing a multilayer structure comprises depositing a coat of graphene ink on a passivation layer; bonding a polymer so-called carrier layer using an adhesive; drying the coat of ink; removing some of the graphene and the passivation layer from a first face without cutting into the polymer carrier layer and while removing the polymer carrier layer and the cut-out zones from the second face; bonding adhesive strips along the longitudinal periphery on each side of the passivation layer and in part of the zones with the cut-out graphene; placing electronic components, electrodes, on a polymer substrate layer; and bonding the passivation layer to the substrate layer with the electronic components in that part of the passivation zones that has the graphene cut out.

### TECHNICAL FIELD

The present invention relates to flexible films containing electronic components or electronic elements or materials. More particularly, the invention concerns a method of manufacturing a flexible multilayer electronic structure in which an electronic part is mounted on an insulating base and covered with an insulating passivation.

### PRIOR ART

Heating films are available with an electrothermal layer between two insulating layers. Flexible films containing electronic components are also known, these films containing electronic components such as resistors, capacitors, or RF antennas, for example. Other flexible films can be used to make batteries. These films often use conductive ink, which must be dried before adding another layer of insulation, for example. Other components can be deposited and bonded, and different elements on different layers need to be electrically connected to each other, making the manufacturing method difficult. One aim of the present invention is to improve such a method, for example by making it faster, among other things.

### SUMMARY OF THE INVENTION

The aim of the present invention is to define a method for manufacturing different types of flexible multilayer electronic structures that is efficient and easy to implement.

According to a first aspect, a method for manufacturing a multilayer, flexible, substantially planar structure is presented. The method comprises the following steps:
depositing a coat of graphene ink on a polymer passivation layer, leaving an ink void at the longitudinal periphery of the polymer passivation layer;
bonding a polymer so-called carrier layer pre-treated with a pressure-sensitive adhesive to the polymer passivation layer;
drying the coat of ink;
removing one or more pieces of graphene by cutting out the graphene zones to be removed and the polymer passivation layer from a first face without cutting into the polymer carrier layer and while removing the polymeric carrier layer and the cut-out zones from the second face;
bonding adhesive strips along the longitudinal periphery on each side of the polymer passivation layer and in part of the zones with the graphene cut out;
placing electronic components, electrodes and interconnects, on a polymer substrate layer; and
bonding the passivation layer to the substrate layer with the electronic components in the part of the passivation zones with the graphene cut out.

According to a second aspect, a flexible, substantially planar, multilayer electronic structure is presented, the structure being manufactured by the above-mentioned method.

### BRIEF DESCRIPTION OF DRAWINGS

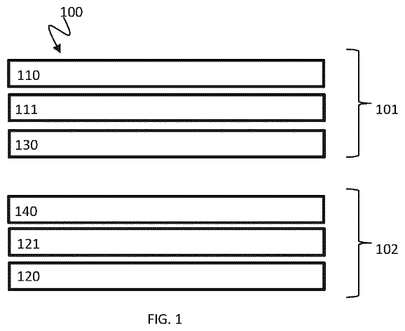

The features of the invention will become clearer on reading the description of several embodiments given by way of example only and in no way limiting, with reference to FIG. 1, wherein the various layers present in an electrothermal structure according to one embodiment described herein are visible.

### DETAILED DESCRIPTION OF THE INVENTION

The present invention relates to a method for manufacturing a flexible multilayer electronic structure. The structure is substantially planar, preferably elongated, extending in two dimensions over a length and a width, the length preferably being several times greater than the width.

The structure is an electronic structure in the sense that it may comprise electronic components or circuits, these circuits or components being either positioned or deposited, or printed by a screen-printing process, for example. Depending on the functionality required, these circuits or components can be resistors, capacitors, diodes, chokes, transistors, or sensors of various types, for example. According to a further embodiment, which may be combined with one or more of the other embodiments mentioned herein, the structure may comprise an electrothermal material for generating heat or cold. The structure may comprise a conductive layer comprising conductive traces for linking components and/or electrothermal elements together to make one or more electrical circuits. In yet another embodiment, the film or multilayer structure can be used to manufacture batteries. In yet another embodiment, such structures can be used to make photovoltaic films.

The electronic part of flexible multilayer electronic structures, which can be manufactured according to one embodiment of the present invention, is located on one or more layers between a substrate and a passivation, the substrate and passivation being electrical insulators, for example a polymer. In a preferred embodiment, the passivation and substrate each comprise two layers of the polymer bonded together. The structure is therefore air- and water-tight, electrically insulating, and mechanically resistant to scratches and/or cuts.

According to one embodiment, the polymer comprises a flexible polymer material, for example polyethylene terephthalate (PET). Other polymers are also possible, for example polyethylene (PE), polypropylene (PP), polyvinyl chloride (PVC), soft PVC (PVC-P), polystyrene (PS), polycarbonate (PC), polymethyl methacrylate (PMMA), polyoxymethylene (POM), polyethylene terephthalate (PET), polyester, co-polyester, polyetheretherketone (PEEK), polyamide, in particular polyamide 6 (PA6), polyamide 12 (PA12), polyamide 10, polyamide 610, polyamide 66, polyamide based on aliphatic and cycloaliphatic constituents such as in particular MACM12 or amorphous co-polyamide, preferably based on PA12, or copolymers or mixtures thereof.

The flexible multilayer electronic structures comprise a base and a cap. The cap comprises the electrothermal layer and the base comprises the conductive layer, which may comprise electronics. According to an embodiment, the flexible multilayer electronic structures of the present invention can be produced on a production line that allows the electronic part to be printed on the passivation to make the base. The cap is then attached to a substrate, that is the base, using glue. In a preferred embodiment, bonding is achieved using an adhesive that acts with mechanical pressure, that is a “PSA” (pressure-sensitive adhesive). A PSA is a type of non-reactive adhesive that forms a bond when pressure is applied to bind the adhesive to a surface.

In one embodiment, a passivation layer is unwound from a first main roller. Optionally, this passivation layer can be wound onto a second main roller. The passivation is preferably a polymer, as described above. To ensure good adhesion of the coats to be applied to the passivation, the passivation can optionally be pre-treated with plasma.

Depending on the type of electronic structure to be made, for example a heating film with an electrothermal layer, a photovoltaic layer or a battery, the structure may comprise graphene. This layer can be produced by depositing graphene ink. The ink can be prepared by mixing graphene with resins and/or solvents.

For electrothermal inks, for example, the molecular structure of graphene is hexagonal in two dimensions. For conductive inks, graphene microparticles or even nanoparticles can be used. Graphene nanoparticles can range in size from 1 nm to 100 nm. In one embodiment, the molecular form of the nanoparticles can be nanotubes, nanospheres, or graphene nanowires, for example.

In one embodiment, a planetary mixer is used to ensure ink homogeneity without air bubbles.

A layer of pre-mixed graphene ink is deposited on the passivation, preferably by a slot die process, while the passivation proceeds under the slot die head. The thickness of this layer can be controlled by regulating the unwinding speed of the polymer. In one embodiment, the ink is stirred or mixed as it is pumped into the slot die head. The pressure of the pump can also be used to control the thickness of the coat of graphene ink. For an electrothermal structure, the graphene does not extend to the edges within the width of the passivation.

The coat of graphene ink is then dried, preferably by a near-infrared (NIR) (short-wave) drying process, which promotes rapid ink drying without damaging the polymer. In one embodiment, the drying takes place in pulses. The inks dry at 120° for around 10 minutes, which is much faster than other non-infrared techniques, which can have speeds of around 6 m/min for a 60 m drying tunnel at 125 degrees, for example. With infrared rays, drying can take around one to two seconds over a distance of 0.5 m or 1 m.

A “carrier” layer is applied over the passivation. This layer can be applied before, during or after the coat of graphene ink. The carrier layer can be made of polymer material. In one embodiment, as shown in FIG. 2, the carrier layer is unwound by a first carrier roller 230 and wound by a second carrier roller 240. This layer can be PET, which is prepared with a layer of PSA glue. Pressure can be exerted on the carrier layer and passivation to make them stick together, for example with a pair of rollers in a roller wringer configuration.

The graphene layer is generally continuous on the passivate after the inking method described above. This layer can be divided into a plurality of graphene blocks, or other defined designs. Recesses are made in the graphene in order to create specific zones of inking on the passivation with defined designs. In a preferred embodiment, the recesses are made with a drum die system to separate predefined inking zones by cuts. The cuts are made in the graphene and polymer layers, right down to the carrier layer. When the carrier layer is removed, the graphene regions that have been cut out—the offcuts—remain stuck to the carrier and can be discarded. In another embodiment, this operation is performed by laser cutting.

A second coat of passivation is applied using a PSA adhesive.

To complete the cap, electrodes are fitted. Optionally, integrated circuits, sensors or RFID modules can be mounted or printed on the cap, along with electrical connectors, to create the desired electronic circuit. The circuits, modules or sensors are placed in the zones that have been hollowed out.

Finally, strips of PSA glue are placed in part of each recess and along the passivation on the graphene-free edges. An adhesive PSA strip or tape can therefore be unwound and attached to the passivation on the two edges of the structure where there is no graphene. The adhesive strip can also be glued in recessed zones, for example pre-cut with the machine in “label” mode.

A substrate polymer layer can be prepared with integrated circuits or electrical components or sensors or antennas or RFID chips or other printed circuitry, as well as electrodes to connect the electronics and/or to connect to the graphene. Like the passivation layer, the substrate layer can be treated with plasma to improve the adhesion of the other layers on top. This substrate layer may also contain deposited or printed connectors, for example to link several structures together. The electrodes and connectors can be formed with conductive ink as described above. This polymeric layer, the base, can be unrolled over the cap, and the cap and base glued together using pre-positioned adhesive strips.

A second polymer passivation layer, prepared with a layer of PSA adhesive, can be bonded to the first passivation layer. Similarly, a second polymer substrate layer, prepared with a PSA adhesive, can be bonded to the first substrate layer.

In an embodiment wherein the structure comprises one or more RFID chips, the method comprises a testing step which comprises reading the RFID chip.

The structure can be cut into long pieces with a given number of graphene blocks.

1. A method for manufacturing a flexible, substantially planar, multilayer structure (100), the method comprising:
depositing a coat of graphene ink on a polymer passivation layer (120, 121) leaving an ink void at the longitudinal periphery of the polymer passivation layer;
bonding a polymer so-called carrier layer pre-treated with a pressure-sensitive adhesive to the polymer passivation layer;
drying the coat of ink;
removing one or more pieces of graphene by cutting out the graphene zones to be removed and the polymer passivation layer from a first face without cutting into the polymer carrier layer and while removing the polymeric carrier layer and the cut-out zones from the second face;
bonding adhesive strips along the longitudinal periphery on each side of the polymer passivation layer and in part of the zones with the graphene cut out;
placing electronic components, electrodes and interconnects, on a polymer substrate layer (110, 111); and
bonding the passivation layer (120, 121) to the substrate layer (110, 111) with the electronic components in the part of the passivation zones with the graphene cut out.

2. The manufacturing method according to claim 1, further comprising:
increasing the substrate thickness by bonding a second polymeric substrate layer (110);
increasing the passivation thickness by bonding a second polymer passivation layer (120).

3. The method according to claim 1, wherein the polymer passivation layer (120, 121) is plasma-treated.

4. The method according to claim 1, wherein the polymer substrate layer (110, 111) is plasma-treated.

5. The method according to claim 1, wherein the graphene ink is dried by infrared treatment.

6. The method according to claim 1, wherein the graphene ink is dried by a short infrared ray treatment.

7. A flexible, substantially planar, multilayer structure (100) manufactured by the method according to claim 1.
